(19) United States
(12) Patent Application Publication
(10) Pub. No.: US 2025/0377567 A1
(43) Pub. Date: Dec. 11, 2025

(54) DISPLAY DEVICE

(71) Applicant: Sharp Display Technology Corporation, Kameyama City (JP)

(72) Inventors: Tetsuo FUKAYA, Kameyama City (JP); Taichi SASAKI, Kameyama City (JP)

(21) Appl. No.: 19/191,613

(22) Filed: Apr. 28, 2025

(30) Foreign Application Priority Data
Jun. 7, 2024 (JP) 2024-093056

(51) Int. Cl. G02F 1/1362; G02F 1/1368; H10D 86/40; H10D 86/60

(52) U.S. Cl. CPC G02F 1/136209; G02F 1/136286; G02F 1/1368; H10D 86/423; H10D 86/60

(57) ABSTRACT

A display device comprises a light source, a first substrate including a switching element including an oxide semiconductor layer, a display layer, and a second substrate, in this order from a back face side to an observation face side; and a plurality of pixels arranged in a matrix in a display region, wherein the first substrate includes a light blocking layer and a reflective layer on the observation face side relative to the switching element, the light blocking layer is positioned between the switching element and the reflective layer, at least a surface of the reflective layer on the back face side has an uneven shape, and each of the plurality of pixels includes a reflective region and a transmissive region, the reflective region is configured to reflect light at the reflective layer and to perform display, and the transmissive region is configured to transmit light and to perform display.

### CROSS-REFERENCE TO RELATED APPLICATIONS

This application claims the benefit of priority to Japanese Patent Application Number 2024-093056 filed on Jun. 7, 2024. The entire contents of the above-identified application are hereby incorporated by reference.

### BACKGROUND

### Technical Field

The disclosure relates to a display device.

Display devices are generally classified into a transmissive type and a reflective type according to image display systems. A transmissive display device performs display in a transmission mode by using transmitted light of light emitted from a backlight unit placed at the back face of a screen. A reflective display device performs display in a reflection mode by using external light (also referred to as ambient light) instead of backlight. The reflective display device does not need a backlight unit and thus can achieve low power consumption, a reduction in thickness, and a reduction in weight. On the other hand, the transmissive display device includes a light source on a back face side and thus has an advantage of high visibility even in dark environment.

Regarding the reflective display device, for example, JP 2004-118039 A proposes a liquid crystal display device in which a semiconductor element configured to drive a pixel electrode, an insulating film covering the semiconductor element, and a reflector formed on the insulating film are formed on an element substrate provided with the pixel electrode, and a light blocking layer configured to block light incident on the semiconductor element is formed on an element substrate side of the semiconductor element.

### SUMMARY

In recent years, as display devices having both features of the transmissive type and the reflective type, transflective display devices have been proposed in which each pixel includes a region (transmissive region) for performing display in the transmission mode and a region (reflective region) for performing display in the reflection mode. Thus, the inventors have studied a transflective display device as follows.

First, a liquid crystal display device 1R, which will be described later in Comparative Example 1, was prepared. The liquid crystal display device 1R includes a backlight unit 40 on a back face side, and a reflective layer 140 having an uneven shape such as a Micro Reflective Structure (MRS). The reflective layer 140 is provided on a side of a first substrate 10 positioned on the back face side, of a pair of substrates sandwiching a liquid crystal layer 20 (see FIG. 11). When the liquid crystal display device IR was driven at a low frequency (1 Hz) and subjected to an aging test for 1000 hours in a state of transmissive display (that is, in a state in which the backlight unit 40 was turned on), a display defect (hazy unevenness) occurred (see FIG. 12).

The inventors have considered that for example, a decrease in off characteristics of a drive element such as a Thin Film Transistor (also referred to as a TFT) due to light from the backlight unit or the like causes the occurrence of the hazy unevenness in Comparative Example 1 and have conducted further detailed studies as follows. Note that the drive element is also referred to as a switching element.

Since a transflective display device uses light from the backlight unit, a TFT channel portion is typically configured to avoid entrance of the light from the backlight unit, for example, by increasing a gate size so that the light does not hit a semiconductor layer (also referred to as the channel portion) of the TFT or by disposing a reflective layer at a position not overlapping the TFT channel portion. However, when the reflective layer 140 has an uneven shape such as the MRS on the back face side, the light from the backlight unit is diffusively reflected due to the uneven shape (see light L1 in FIG. 11), and the diffusively reflected light is directly or indirectly incident on the TFT channel portion. That is, since light irradiation to the TFT channel portion and gate bias stress exist at the same time, characteristics of a gate threshold voltage Vth of the TFT is shifted. In particular, at the time of driving at a low frequency, since almost only a negative bias is applied to the gate, a time period for applying the negative bias to the gate is long. In this case, when light is incident on the TFT, Vth of the TFT significantly shifts to the negative side. Thus, even when a negative voltage is applied to the TFT, required off characteristics are not obtained, that is, a current flowing from the gate cannot be sufficiently blocked. As a result, an abnormal voltage is applied to the pixel, and clustered bright spots or clustered black spots occur when gray level display is performed (see FIG. 12). Such clustered bright spots or clustered black spots are referred to as “hazy unevenness” in the present specification.

Here, in a transmissive display device, light from a backlight unit is blocked by a gate of a TFT, a light blocking film provided on a back face side relative to a TFT channel portion, or the like, and ambient light is blocked by a black matrix provided on a substrate or the like on an observation face side. In addition, in a reflective display device, since a light source is not provided on a back face side, light from a backlight unit does not exist, and ambient light is also blocked by a gate of a TFT or the like. Thus, in the transmissive and reflective display devices, the above-described phenomenon does not occur (for example, see Comparative Example 2, which will be described later). On the other hand, in the transflective display device, although light from the backlight unit is blocked by the gate of the TFT or the like and ambient light is blocked by a black matrix as in the transmissive display device, the light from the backlight unit (indirect light) reflected by a reflector enters the TFT because the reflector is typically formed on an observation face side relative to the TFT. Thus, the above-described phenomenon occurs.

Note that as a measure for improving off characteristics of a switching element, for example, as disclosed in JP 2004-118039 A, the light blocking layer configured to block entrance of light into the semiconductor element may be provided on the element substrate side of the semiconductor element. However, even when this measure is taken, it is difficult to reduce the occurrence of the hazy unevenness (see Comparative Example 3, which will be described later).

The disclosure has been made in view of the above-described circumstances, and an object of the present disclosure is to provide a transflective display device in which off characteristics of a switching element are favorable and display quality is excellent even when power consumption is low.

(1) An embodiment of the disclosure is a display device including a light source, a first substrate including a switching element including an oxide semiconductor layer, a display layer, and a second substrate, in this order from a back face side to an observation face side, and a plurality of pixels arranged in a matrix in a display region, in which the first substrate includes a light blocking layer and a reflective layer on the observation face side relative to the switching element, the light blocking layer is positioned between the switching element and the reflective layer, at least a surface of the reflective layer on the back face side has an uneven shape, and each of the plurality of pixels includes a reflective region and a transmissive region, the reflective region is configured to reflect light at the reflective layer and to perform display, and the transmissive region is configured to transmit light and to perform display.

(2) In a display device according to an embodiment of the disclosure, in addition to the configuration (1), the first substrate includes an interlayer insulating film between a source bus line and a drain wiring line each of which is electrically connected to the switching element and the light blocking layer.

(3) In a display device according to an embodiment of the disclosure, in addition to the configuration (1) or (2), the light blocking layer is a circular polarization plate.

(4) In a display device according to an embodiment of the disclosure, in addition to the configuration (3), each of the plurality of pixels includes a pixel electrode electrically connected to the switching element, and in the reflective region of each of the plurality of pixels, the light blocking layer and the pixel electrode are disposed on the back face side relative to the reflective layer in an order of the pixel electrode and the light blocking layer.

(5) In a display device according to an embodiment of the disclosure, in addition to the configuration (4), the first substrate includes an interlayer insulating film between the pixel electrode and the light blocking layer.

(6) In a display device according to an embodiment of the disclosure, in addition to the configuration (1) or (2), the light blocking layer is a light absorption layer.

(7) In a display device according to an embodiment of the disclosure, in addition to the configuration (6), the light blocking layer is made of a black inorganic material and/or a black organic material.

(8) In a display device according to an embodiment of the disclosure, in addition to the configuration (6) or (7), each of the plurality of pixels includes a pixel electrode electrically connected to the switching element, and in the reflective region of each of the plurality of pixels, the light blocking layer and the pixel electrode are disposed on the back face side relative to the reflective layer in an order of the pixel electrode and the light blocking layer.

(9) In a display device according to an embodiment of the disclosure, in addition to the configuration (8), in the reflective region of each of the plurality of pixels, the observation face side of the pixel electrode is in contact with the reflective layer, and the back face side of the pixel electrode is in contact with the light blocking layer.

(10) In a display device according to an embodiment of the disclosure, in addition to the configuration (6) or (7), each of the plurality of pixels includes a pixel electrode electrically connected to the switching element, and in the reflective region of each of the plurality of pixels, the light blocking layer and the pixel electrode are disposed on the back face side relative to the reflective layer in an order of the light blocking layer and the pixel electrode.

(11) In a display device according to an embodiment of the disclosure, in addition to the configuration (10), in the reflective region of each of the plurality of pixels, the observation face side of the light blocking layer is in contact with the reflective layer, and the back face side of the light blocking layer is in contact with the pixel electrode.

(12) In a display device according to an embodiment of the disclosure, in addition to the configuration (6), (7), (8), (9), (10), or (11), at least a surface of the light blocking layer on the back face side has an uneven shape.

(13) In a display device according to an embodiment of the disclosure, in addition to the configuration (4), (5), (6), (7), (8), (9), (10), or (11), at least a surface of the pixel electrode on the back face side has an uneven shape.

(14) In a display device according to an embodiment of the disclosure, in addition to the configuration (1), (2), (3), (4), (5), (6), (7), (8), (9), (10), (11), (12), or (13), a polarization plate is provided on the observation face side relative to the second substrate.

(15) In a display device according to an embodiment of the disclosure, in addition to the configuration (1), (2), (3), (4), (5), (6), (7), (8), (9), (10), (11), (12), (13), or (14), the display layer is a liquid crystal layer.

(16) In a display device according to an embodiment of the disclosure, in addition to the configuration (1), (2), (3), (4), (5), (6), (7), (8), (9), (10), (11), (12), (13), (14), or (15), the display device further includes a drive circuit configured to drive the display device, and the drive circuit is configured to switch between a first drive mode and a second drive mode, and in the first drive mode, the display device is configured to be driven at a first frequency, and in the second drive mode, the display device is configured to be driven at a second frequency lower than the first frequency.

(17) In a display device according to an embodiment of the disclosure, in addition to the configuration (16), the light source is turned on in the second drive mode.

(18) In a display device according to an embodiment of the disclosure, in addition to the configuration (1), (2), (3), (4), (5), (6), (7), (8), (9), (10), (11), (12), (13), (14), (15), (16), or (17), the oxide semiconductor layer includes InGaZnOx including indium (In), gallium (Ga), zinc (Zn), and oxygen (O) as main components.

According to the disclosure, it is possible to provide a transflective display device in which off characteristics of a switching element are favorable and display quality is excellent even when power consumption is low.

### BRIEF DESCRIPTION OF DRAWINGS

The disclosure will be described with reference to the accompanying drawings, wherein like numbers reference like elements.

FIG. 1 is a schematic cross-sectional view illustrating a structure of a display device 1 according to first and second embodiments.

FIG. 2 is a schematic plan view of a pixel included in the display device 1 according to the first embodiment.

FIG. 3 is a cross-sectional view taken along a line A-A′ in FIG. 2.

FIG. 4 is a cross-sectional view taken along a line B-B′ in FIG. 2.

FIG. 5 is a schematic cross-sectional view more specifically illustrating a first substrate 10 illustrated in FIG. 3.

FIG. 6 is an enlarged view around a light blocking layer 130 of the first substrate 10 illustrated in FIG. 5.

FIG. 7 is a schematic plan view of a pixel included in the display device 1 according to the second embodiment.

FIG. 8 is a cross-sectional view taken along a line C-C′ in FIG. 7.

FIG. 9 is a schematic cross-sectional view more specifically illustrating the first substrate 10 illustrated in FIG. 8.

FIG. 10 is a schematic cross-sectional view specifically illustrating the first substrate 10 included in the display device 1 according to a first modification of the second embodiment.

FIG. 11 is a schematic cross-sectional view specifically illustrating the first substrate 10 included in a liquid crystal display device 1R according to Comparative Example 1.

FIG. 12 is a plan view conceptually illustrating a state of a display region AA after performing an aging test for 1000 hours in Comparative Example 1.

FIG. 13 is a plan view conceptually illustrating a state of the display region AA before an aging test in Comparative Example 1, Example 1, and Example 2.

FIG. 14 is a schematic cross-sectional view specifically illustrating the first substrate 10 included in a liquid crystal display device 2R according to Comparative Example 2.

FIG. 15 is a schematic cross-sectional view specifically illustrating the first substrate 10 included in a liquid crystal display device 3R according to Comparative Example 3.

FIG. 16 is a plan view conceptually illustrating a state of the display region AA after performing an aging test for 1000 hours in Examples 1 and 2.

### DESCRIPTION OF EMBODIMENTS

### Definition of Terms

In this specification, an “observation face side” refers to a side closer to a screen (display surface) of a display device (that is, a side on which an observer is positioned), and a “back face side” refers to a side farther from the screen (display surface) of the display device.

An axis orientation of an optical film means an orientation of a polarization axis in a case of a polarizer (or a polarization plate) and means an orientation of an in-plane slow axis in a case of a retarder. The polarization axis means an absorption axis in a case of an absorptive polarization plate and means a reflection axis in a case of a reflective polarization plate. An in-plane retardation Re is defined by Re=(nx−ny)×d. nx represents a principal refractive index in an in-plane slow axis direction of each retarder. ny represents a principal refractive index in an in-plane fast axis direction of each retarder. Note that the numerical values described in the present specification as Re are absolute values unless otherwise specified. A measurement wavelength for optical parameters such as refractive indices and retardations is 550 nm unless otherwise specified.

A display device according to an embodiment of the disclosure will be described below. The disclosure is not limited to the contents described in the following embodiments, and appropriate design changes can be made within the scope that satisfies the configuration according to the disclosure. Note that in the description below, the same reference signs are appropriately used in common among the different drawings for the same parts or parts having similar functions, and repeated description thereof will be omitted as appropriate. The aspects of the disclosure may be combined as appropriate within the range that does not depart from the gist of the disclosure.

Hereinafter, embodiments in which the display device 1 is a liquid crystal display device, that is, embodiments in which a display layer 20 is a liquid crystal layer will be mainly described. However, the display device 1 according to the disclosure is not particularly limited thereto as long as the display device includes a backlight unit and a reflective layer. Examples of the display device 1 according to the disclosure include, in addition to the liquid crystal display device, a Micro Electro Mechanical System Display (MEMS Display) or the like.

### First Embodiment

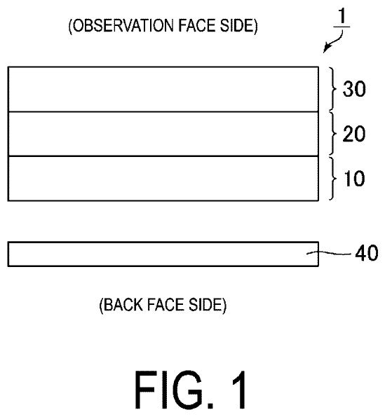

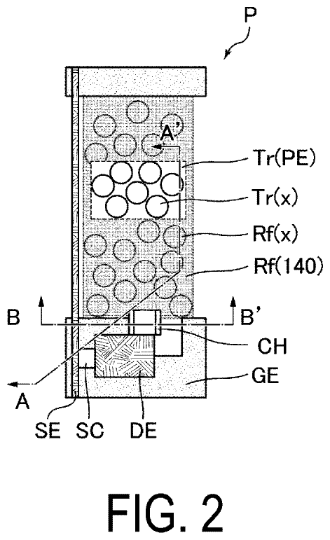

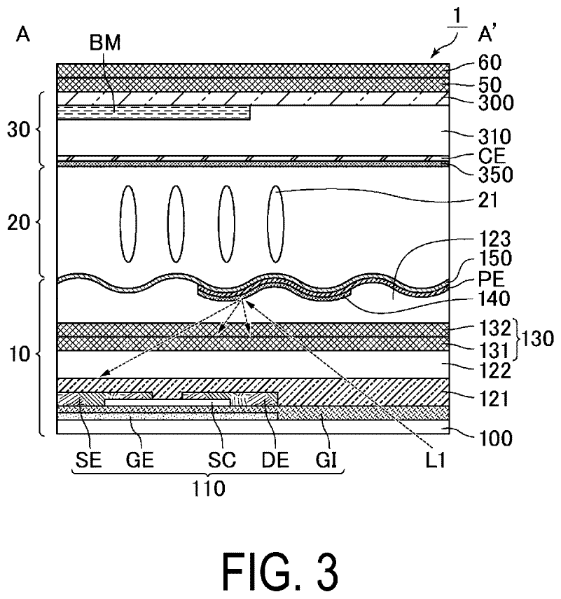

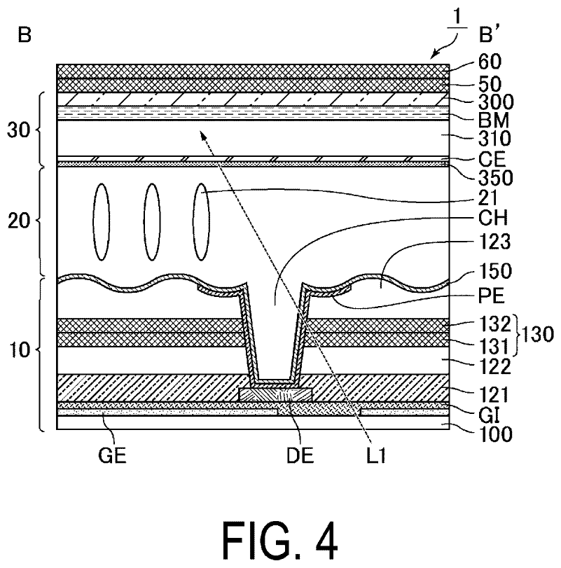

FIG. 1 is a schematic cross-sectional view illustrating a structure of the display device 1 according to the present embodiment (and a second embodiment, which will be described later), and FIG. 2 is a schematic plan view of a pixel included in the display device 1 according to the present embodiment. FIG. 3 is a cross-sectional view taken along a line A-A′ in FIG. 2, and FIG. 4 is a cross-sectional view taken along a line B-B′ in FIG. 2. The display device 1 according to the present embodiment includes a light source 40, a first substrate 10, a display layer 20, and a second substrate 30 in this order from a back face side toward an observation face side.

The light source 40 disposed on the back face side is also referred to as a backlight unit. The light source 40 is not particularly limited as long as the light source 40 emits light, and may be a direct type, an edge type, or any other type. For example, the light source 40 preferably includes a light source such as a Light Emitting Diode (LED), a light guide plate, and a reflective sheet, and may further include a diffuser sheet or a prism sheet.

The display device 1 includes a plurality of pixels P arranged in a matrix in a display region. Although the plurality of pixels P typically include three types of pixels, that is, a red pixel, a green pixel, and a blue pixel, the number of types of pixels may be two or less or four or greater. Each of the plurality of pixels P includes a reflective region Rf for display by reflecting light (that is, a region for display in a reflection mode) at the reflective layer 140 and a transmissive region Tr for display by transmitting light (a region for display in a transmission mode) (see FIG. 2). This makes it possible to exhibit favorable viewability in any environment. In FIG. 2, Tr(x) represents a protruding portion of the transmissive region Tr, and Rf(x) represents a protruding portion of the reflective region Rf.

A proportion of an area occupied by the transmissive region Tr (aperture ratio) in each pixel P can be set as appropriate depending on an application or the like, but is preferably 5% or more and 95% or less, for example, when the area of one pixel P is taken as 100%. A position and a shape of the transmissive region Tr within the pixel P may also be appropriately set depending on the application or the like.

The reflective layer 140 is disposed in the reflective region Rf (see FIG. 3). In the reflective region Rf, light from the observation face side enters the liquid crystal display device 1, is reflected at the reflective layer 140, and then is emitted from the observation face side. In addition, in the display device 1 according to the present embodiment, the light blocking layer 130 is disposed on the back face side of the reflective layer 140. Light from the back face side (for example, light from the backlight unit) is reflected at the reflective layer 140 and then is mostly blocked by the light blocking layer 130 (see light L1). On the other hand, the reflective layer 140 is not disposed in the transmissive region Tr (see FIG. 3). In the transmissive region Tr, light from the backlight unit is transmitted through the display layer 20 and is emitted from the observation face side. Note that when the second substrate 30 includes a light blocking portion such as a black matrix layer BM, light from the observation face side enters the display device 1 and then is absorbed by the black matrix layer BM. In addition, light from the backlight unit may be reflected at, for example, a gate electrode GE of a TFT 110 and emitted from the back face side (see light L2). Arrows in FIG. 3 indicate an optical path and traveling directions of light from the back face side (for example, light from the backlight unit).

The first substrate 10 is formed with a switching element 110 including an oxide semiconductor layer SC, the light blocking layer 130, the reflective layer 140, a pixel electrode PE, and the like on a surface of a support substrate 100. In the present embodiment, a TFT is used as the switching element 110. The TFT 110 includes the oxide semiconductor layer SC and TFT electrodes. The TFT electrodes include terminals of the TFT 110 (a gate, a source, and a drain) and wiring lines electrically connected to the respective terminals, and made of a metal or an alloy. An insulating layer (also referred to as an insulating film) may be provided between the layers and the like (for example, a gate insulating film GI, interlayer insulating layers 121 to 123, and the like).

The TFT 110 is provided in each of the plurality of pixels P. The luminance of each pixel P is controlled by controlling a voltage to be applied to the pixel electrode PE. The pixel electrode PE is electrically connected to a drain electrode DE of the TFT 110 (see FIG. 4), and the drain electrode DE is connected to a source electrode SE through the oxide semiconductor layer SC. A current flowing through the oxide semiconductor layer SC is controlled by a voltage applied to the gate electrode GE. The gate electrode GE, the source electrode SE, and the drain electrode DE are included in the TFT electrodes.

The oxide semiconductor included in the oxide semiconductor layer SC contains, for example, at least one metal element selected from indium (In), gallium (Ga), and zinc (Zn). As the oxide semiconductor, specifically, a compound (In—Ga—Zn—O) made of In, Ga, Zn, and oxygen (O), a compound (In-Tin-Zn—O) made of In, tin (Tin), Zn, and O, a compound (In—Al—Zn—O) made of In, aluminum (Al), Zn, and O, or the like may be used. Among these, In—Ga—Zn—O is preferable.

As described above, the oxide semiconductor layer SC is preferably a layer containing InGaZnox, which contains In, Ga, Zn, and O as main components. Here, a proportion (composition ratio) of In, Ga, and Zn is not particularly limited thereto, and for example, In:Ga:Zn=2:2:1, In:Ga:Zn=1:1:1, In:Ga:Zn=1:1:2, and the like may be exemplified. InGaZnOx may be amorphous or crystalline. As InGaZnOx that is crystalline, a c-axis is suitably oriented approximately perpendicular to a layer surface.

The reflective layer 140 is provided on the observation face side relative to the TFT 110, and the light blocking layer 130 is provided on the back face side relative to the reflective layer 140. That is, the TFT 110, the light blocking layer 130, and the reflective layer 140 are disposed in this order from the back face side toward the observation face side. One or more interlayer insulating films are provided between the TFT 110 and the light blocking layer 130. To be more specific, the first substrate 10 preferably includes an interlayer insulating layer (for example, a first interlayer insulating layer 121 and a second interlayer insulating layer 122 in FIG. 3 and FIG. 4) between a source bus line SE and a drain wiring line DE that are electrically connected to the TFT 110 and the light blocking layer 130. Since the light blocking layer 130 is disposed on the observation face side relative to the source bus line SE and the drain wiring line DE, the display device 1 can more remarkably exhibit an effect of suppressing deterioration in TFT characteristics (in particular, off characteristics).

At least a surface of the reflective layer 140 on the back face side has an uneven shape (also referred to as an uneven surface structure). The uneven surface structure is also called Micro Reflective Structure (MRS), and is provided to diffusely reflect ambient light and achieve white display close to paper white. The uneven surface structure is preferably configured of a plurality of protruding portions p randomly arranged, for example, such that a center interval between the adjacent protruding portions p is 5 μm or greater and 50 μm or less. A center interval between the adjacent protruding portions p is more preferably 10 μm or more and 20 μm or less. A shape of each protruding portion p is substantially circular or substantially polygonal when viewed from a normal direction of the support substrate 100. An area of the protruding portion p occupying one pixel P is preferably about 20 to 40%, for example, and a height of the protruding portion p is preferably 1 μm or greater and 5 μm or less, for example. A surface of the reflective layer 140 on the observation face side may or need not have an uneven shape.

The reflective layer 140 is made of a material that reflects light. The reflective layer 140 is preferably made of a metal material having high reflectivity. Examples of the material of the reflective layer 140 include aluminum, silver, a silver alloy, and an aluminum alloy.

A thickness (a total thickness in a case of a layered structure) of the reflective layer 140 is not particularly limited and is, for example, 1 nm to 1 μm.

In the present embodiment, the pixel electrode PE electrically connected to the TFT 110 through a contact hole CH is disposed between the reflective layer 140 and the light blocking layer 130 (see FIG. 4). It is preferable that the reflective layer 140 be not disposed in the contact hole CH connecting the drain electrode DE and the pixel electrode PE. This suppresses (diffused) reflection of light from the backlight unit in the vicinity of the contact hole CH, so that there is no problem even when transmitted light in this vicinity is not polarized. Thus, the light blocking layer 130 may have an opening at a portion where the contact hole CH is provided (see FIG. 4). Note that when the light blocking layer 130 has an opening, it is preferable that the opening and, for example, the black matrix layer BM included in the second substrate 30 or a metal wiring line or the like of the first substrate 10 be disposed so as to overlap each other in a plan view, thereby blocking light at the opening (see FIG. 4). That is, in the reflective region Rf of each pixel P, it is preferable that the light blocking layer 130 and the pixel electrode PE be disposed on the back face side relative to the reflective layer 140 in an order of the pixel electrode PE and the light blocking layer 130 from the reflective layer 140 side (see FIG. 3 and FIG. 4).

One or more transparent layers (for example, a transparent electrode or an interlayer insulating layer) may be disposed between the reflective layer 140 and the pixel electrode PE, but it is preferable that the pixel electrode PE be disposed in contact with the reflective layer 140. The pixel electrode PE may be disposed on the back face side of a part of the reflective layer 140 but is preferably disposed on the back face side of the entire surface of the reflective layer 140 in consideration of cost and efficiency in manufacturing the display device 1.

The pixel electrode PE is preferably a transparent electrode. The transparent electrode may be preferably formed using, for example, an electrically conductive material that is transparent such as indium tin oxide (ITO), indium zinc oxide (IZO), zinc oxide (ZnO), or tin oxide (SnO), or an alloy thereof.

It is preferable that at least the surface of the pixel electrode PE on the back face side have an uneven shape (uneven surface structure), and it is more preferable that both the surface on the observation face side and the surface on the back face side of the pixel electrode PE have uneven shapes. For example, by using an organic insulating film having an uneven surface structure as at least one layer (for example, a third interlayer insulating layer 123 in FIG. 3 and FIG. 4) of the interlayer insulating layers disposed between the pixel electrode PE and the light blocking layer 130, the layers and the like (the pixel electrode PE and the reflective layer 140 in the present embodiment) positioned on the observation face side of the interlayer insulating layer can have uneven shapes reflecting the uneven surface structure.

As described above, one or more interlayer insulating layers are preferably disposed between the pixel electrode PE and the light blocking layer 130. Also, one layer or two or more layers of the interlayer insulating layers are preferably disposed between the TFT 110 and the light blocking layer 130. In FIG. 3 and FIG. 4, the first interlayer insulating layer 121 and the second interlayer insulating layer 122 are provided between the TFT 110 and the light blocking layer 130, and the third interlayer insulating layer 123 is provided between the light blocking layer 130 and the pixel electrode PE. The contact hole CH is formed at the interlayer insulating layers disposed between the pixel electrode PE and the TFT 110, and the pixel electrode PE is electrically connected to the TFT 110 through the contact hole CH. In other words, in the reflective region Rf of each pixel P, the first substrate 10 preferably includes the switching element 110, the interlayer insulating layers (the first interlayer insulating layer 121 and the second interlayer insulating layer 122 in FIG. 3 and FIG. 4), the light blocking layer 130, the interlayer insulating layer (the third interlayer insulating layer 123 in FIG. 3 and FIG. 4), the pixel electrode PE, and the reflective layer 140 in this order from the back face side toward the observation face side (see FIG. 3 and FIG. 4).

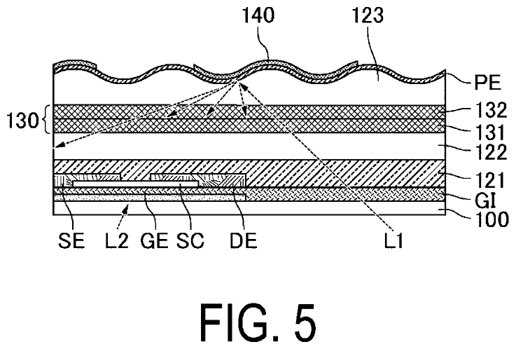

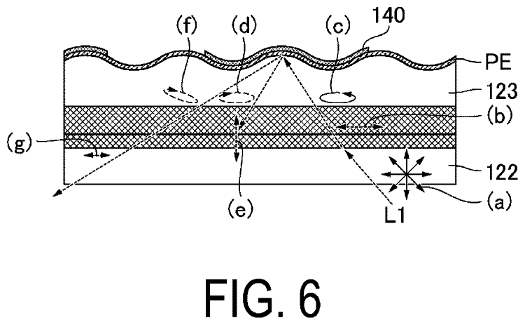

In the present embodiment, the light blocking layer 130 is a circular polarization plate. The circular polarization plate includes a polarizer 131 and a λ/4 plate 132. A positional relationship between the polarizer 131 and the λ/4 plate 132 is preferably in an order of the polarizer 131 and the λ/4 plate 132 from the back face side toward the observation face side (see FIG. 5 and FIG. 6). FIG. 5 is a schematic cross-sectional view more specifically illustrating the first substrate 10 illustrated in FIG. 3 and the like, and FIG. 6 is an enlarged view around the light blocking layer 130 of the first substrate 10 illustrated in FIG. 5 (an alignment film 150 is omitted). FIG. 6 is also a diagram for describing a polarization state of light from the backlight unit.

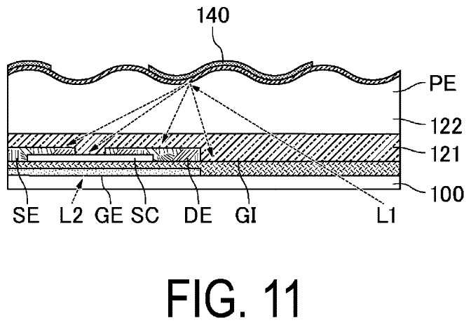

In a transflective display device that does not include the light blocking layer 130, when the light L1 from the backlight unit hits the reflective layer 140, the light L1 may be reflected and enter the TFT channel portion. Since TFT characteristics are different between a case where light from the backlight unit enters the TFT channel portion and a case where light from the backlight unit does not enter the TFT channel portion, the display quality of such a display device is not favorable. In particular, when the surface of the reflective layer 140 on the back face side has an uneven shape, light is diffusely reflected and easily reaches the TFT channel portion, and thus the influence of reflection of light from the backlight unit increases (see FIG. 11).

However, in the present embodiment, the light blocking layer 130 is disposed on the back face side relative to the reflective layer 140. As illustrated in FIG. 6, when the light L1 (randomly polarized light; see (a) in FIG. 6) from the backlight unit 40 is incident on the light blocking layer 130, the light L1 becomes linearly polarized light when emitted from the polarizer 131 (see (b) in FIG. 6) and becomes circularly polarized light when subsequently emitted from the λ/4 plate 132 (see (c) in FIG. 6). Thereafter, the light L1 is rotationally reflected at the reflective layer 140 to become circularly polarized light in a state different from that illustrated in (c) in FIG. 6 (see (d) in FIG. 6) and becomes linearly polarized light rotated by 90° from that illustrated by (b) in FIG. 6 when entering the polarizer 131 again (see (e) in FIG. 6). Thus, the light L1 is blocked by the polarizer 131 and cannot reach the TFT 110 positioned on the back face side. Note that when the reflected light has a high polar angle, an optical path length formed by the λ/4 plate 132 is increased, so that polarized light is degraded (see (f) in FIG. 6) and does not become linearly polarized light rotated by 90° on the polarizer 131 and thus passes through the light blocking layer 130 (see (g) in FIG. 6). As described above, a part of the reflected light passes through the light blocking layer 130 but a light amount thereof is small. Therefore, since a negative shift of the TFT characteristics is sufficiently suppressed, the display device 1 according to the present embodiment has excellent off characteristics of the TFT, and thus the display defect (hazy unevenness) does not occur. Note that each polarized light of (a) to (g) illustrated in FIG. 6 is an example.

As the polarizer 131, for example, an absorptive polarizer, a reflective polarizer, and the like are preferably used. Examples of the polarizer 131 include an absorptive polarizer obtained by absorbing and aligning an anisotropic material such as an iodine complex having dichroism onto a polyvinyl alcohol film; a reflective polarizer obtained by uniaxially stretching a coextrusion film made of two kinds of resin (for example, APCF manufactured by Nitto Denko Corporation and DBEF manufactured by 3M); and a reflective polarizer obtained by periodically arranging thin metal wires (so-called wire grid polarizer). As the polarizer 131, a polarizer obtained by layering an absorptive polarizer and a reflective polarizer may be used. In particular, the polarizer 131 is preferably an absorptive polarizer. In addition, a shape of the polarizer 131 may be a plate shape but is preferably not a plate shape in consideration of yield and cost.

The λ/4 plate means a retarder that imparts an in-plane retardation of a ¼ wavelength to incident light having a wavelength λ and is also referred to as a λ/4 wavelength plate or a Quarter-Wave Plate (QWP). The λ/4 plate 132 can convert linearly polarized light into circularly polarized light or convert circularly polarized light into linearly polarized light. For example, linearly polarized light incident on the λ/4 plate 132 becomes circularly polarized light when the light is emitted from the λ/4 plate 132.

The insulating layer is preferably a layer made of an organic insulating material or an inorganic insulating material. Examples of the organic insulating film obtained by using the organic insulating material include an organic film (with a relative dielectric constant ε=2 to 5) such as acrylic resin, polyimide resin, and novolac resin, and a layered body thereof. A film thickness of the organic insulating film is not particularly limited, but is 2 μm or more and 4 μm or less, for example. Examples of the inorganic insulating films obtained by using the inorganic insulating material include an inorganic film (with a relative dielectric constant ε=3 to 7) such as silicon nitride (SiNx) and silicon oxide (SiO₂), and a layered film thereof. A film thickness of the inorganic insulating film is not particularly limited, but is 1500 Å or more and 3500 Å or less, for example. Alternatively, the insulating layer may be a layered body of the organic insulating film and the inorganic insulating film. Among the insulating layers, the gate insulating film GI is preferably the inorganic insulating film, the first interlayer insulating layer 121 disposed so as to cover the TFT 110 is preferably the inorganic insulating film, and the interlayer insulating layers (for example, the second interlayer insulating layer 122, the third interlayer insulating layer 123, and the like in FIG. 3 and FIG. 4) disposed on the observation face side relative to the first interlayer insulating layer 121 is preferably the organic insulating film. In addition, each insulating layer preferably has high transparency and is preferably made of a material having a high transmittance.

The first substrate 10 includes a flattening film (not illustrated) on the observation face side relative to the reflective layer 140. The flattening film is preferably disposed not only in the reflective region Rf but also in the transmissive region Tr. The flattening film is preferably an insulating film, more preferably an organic insulating film. Details of the organic insulating film are as described above. Disposing the flattening film on the observation face side relative to the reflective layer 140 allows an interface between the first substrate 10 and the display layer 20 to have a flat shape. Thus, since a holding capacitance is formed in the flat region, the display device 1 according to the present embodiment has a stabilized capacitance, and thus the display quality does not deteriorate, so that the display device 1 can have high quality.

The second substrate 30 is a substrate disposed so as to face the first substrate 10. For example, the second substrate 30 is obtained by forming the black matrix layer BM, a common electrode CE, and the like on a surface of a support substrate 300. Although FIG. 2 to FIG. 4 illustrate the pixel structure of the display device 1 that performs monochrome display, the display device 1 of the present embodiment may perform color display. In this case, the second substrate 30 may include a color resist layer CR. The color resist layer CR may include a color filter for one or more colors (for example, red, green, blue, and the like). Further, at least one of the color resist layer CR and the black matrix layer BM may be disposed on the first substrate 10.

The common electrode CE is preferably a transparent electrode. The transparent electrode is as described above. Additionally, the second substrate 30 may include an overcoat layer 310. The overcoat layer 310 is preferably an insulating film, and more preferably an organic insulating film. Details of the organic insulating film are as described above.

Each of the support substrate 100 and the support substrate 300 is preferably a substrate being transparent and having an insulating property, and for example, is preferably a glass substrate or a plastic substrate.

The display layer 20 is disposed between the first substrate 10 and the second substrate 30 (see FIG. 1 and FIG. 2). The first substrate 10 or the second substrate 30 and the display layer 20 may be in direct contact with each other, or one layer or two or more layers of other layers (for example, alignment films 150 and 350) may be disposed between the first substrate 10 or the second substrate 30 and the display layer 20.

The display layer 20 is a layer that performs display by controlling the passage of visible light, and is also referred to as an optical shutter layer. Although the display layer 20 is a liquid crystal layer in the present embodiment, the display layer 20 may be a shutter layer that controls blocking or transmitting of light by sliding a shutter body. In particular, the display layer 20 is preferably a liquid crystal layer.

When the display layer 20 is a liquid crystal layer, that is, when the display device 1 is a liquid crystal display device, the liquid crystal display mode is not particularly limited, and may be any liquid crystal display mode such as a Vertical Alignment (VA) mode, a horizontal alignment (ECB) mode, a Twisted Nematic (TN) mode, a Fringe Field Switching (FFS) mode, or an In-Plane Switching (IPS) mode, for example. Note that the pixel structure illustrated in FIG. 2 and the like is an example of the VA mode.

The display device 1 preferably further includes a polarization plate 60 on the observation face side relative to the second substrate 30. Additionally, the display device 1 preferably further includes a retarder 50 on the observation face side relative to the second substrate 30. When the display device 1 includes the retarder 50 and the polarization plate 60 on the observation face side relative to the second substrate 30, the retarder 50 and the polarization plate 60 are preferably disposed in an order of the retarder 50 and the polarization plate 60 from the back face side toward the observation face side (see FIG. 3 and FIG. 4).

The retarder 50 is preferably a λ/4 plate. In this case, the retarder 50 and the λ/4 plate 132 configuring the light blocking layer 130 preferably have substantially the same in-plane retardation Re. The expression “substantially the same” means that a difference between these in-plane retardations Re is less than 5 nm. The difference between the in-plane retardations Re is preferably less than 1 nm.

The polarization plate 60 may be, for example, a reflective polarization plate, but is preferably an absorptive polarization plate. The polarization plate 60 disposed on the observation face side of the second substrate 30 and the polarizer 131 configuring the light blocking layer 130 may be disposed in a parallel-Nicols state but are preferably disposed in a crossed-Nicols state from the viewpoint of obtaining high contrast.

The display device 1 preferably includes a drive circuit (not illustrated) that drives the display device 1, and the drive circuit is preferably capable of switching between a first drive mode and a second drive mode. In the first drive mode, the display device 1 is driven at a first frequency H1 and in the second drive mode, the display device 1 is driven at a second frequency H2 lower than the first frequency H1. It is preferable that the light source 40 be turned on in the second drive mode. For example, the first frequency H1 is from 30 Hz to 120 Hz, and the second frequency H2 is from 0.001 Hz to 30 Hz (where H2<H1 holds). The display device 1 according to the present embodiment has favorable TFT characteristics and excellent display quality even when driven at a low frequency.

In addition to the above-described layers, members, and the like, the display device 1 may further include, for example, an optical film such as a viewing angle enhancement film, or a brightness enhancement film; an external circuit such as a Tape Carrier Package (TCP) or a Printed Circuit Board (PCB); a bezel (frame); and the like. Such members are not particularly limited thereto, and those commonly used in the field of display devices can be used, and thus, description will be omitted.

Next, a preferred manufacturing method for the display device 1 according to the present embodiment will be described.

The display device 1 can be obtained by individually preparing the first substrate 10 and the second substrate 30, and then bonding these substrates with the display layer 20 interposed therebetween. For example, when the display layer 20 is a liquid crystal layer, a liquid crystal material is injected between the first substrate 10 and the second substrate 30 by a general method, thereby obtaining a liquid crystal display device. Note that the second substrate 30 can be prepared according to a manufacturing method for a general color filter substrate.

The first substrate 10 is prepared, for example, according to a manufacturing method for a general transflective display device, and a portion of the TFT 110 is prepared, for example, in accordance with a method for preparing a TFT using a general inverted staggered type oxide semiconductor. Specifically, for example, the following manufacturing method is preferably adopted. That is, the gate insulating film GI is disposed after a gate electrode and a wiring line pattern of the TFT 110 are prepared, on the support substrate 100. Next, after the oxide semiconductor layer SC is formed and a source/drain electrode pattern is formed, the first interlayer insulating layer 121 constituted by, for example, an inorganic insulating film is formed by deposition patterning. After that, an organic insulating film is applied to form the second interlayer insulating layer 122, and then the light blocking layer 130 that is a circular polarization plate is formed. An organic insulating film is further applied thereon to form the third interlayer insulating layer 123, and patterning is performed using a halftone mask or the like, thereby forming the uneven shape of the MRS on the surface of the third interlayer insulating layer 123 on the observation face side. Thereafter, a transparent electrode (for example, ITO) is formed as the pixel electrode PE, and further, the reflective layer 140 is formed. In this manner, the first substrate 10 is suitably prepared.

In the above-described manufacturing method, the light blocking layer 130 that is the circular polarization plate is preferably formed as follows, for example. That is, after forming the second interlayer insulating layer 122, the polarizer 131 is applied thereon. As a method for applying the polarizer 131, for example, JP 2021-182109 A or JP 2020-85931 A can be referred to. First, a liquid crystal composition obtained by mixing a dichroic pigment serving as a guest material with a photopolymerizable liquid crystal compound serving as a host material (that is, a liquid crystal compound having a polymerizable functional group that can be polymerized by light irradiation) in an appropriate solvent is applied on a transparent substrate having an alignment film serving as an underlayer so as to have a predetermined film thickness by using a known coating apparatus such as a spin coater or a slit coater. Thereafter, the solvent is evaporated by heating and drying, and then, the photopolymerizable liquid crystal compound is further polymerized by ultraviolet irradiation to fix alignment of the photopolymerizable liquid crystal compound. In this way, a coating type polarization plate in which the photopolymerizable liquid crystal compound is aligned in a certain direction is suitably formed as the polarizer 131. The λ/4 plate 132 is applied on the polarizer 131. A coating method for the λ/4 plate 132 is substantially similar to the coating method for the polarizer 131 except that a photopolymerizable liquid crystal compound not using a dichroic pigment is used. Note that the λ/4 plate 132 is preferably disposed such that the in-plane slow axis thereof is within a range of “45°+90°×n±5°” (n is an integer) with respect to the polarization axis (absorption axis or reflection axis) of the polarizer 131.

Note that the reflective layer 140 is not disposed in the transmissive region Tr in each pixel P. For example, the reflective region Rf including the reflective layer 140 and the transmissive region Tr not including the reflective layer 140 can be formed by forming the reflective layer 140 and the like and then removing a part of the reflective layer 140 in manufacturing the first substrate 10.

### Second Embodiment

In the first embodiment, the light blocking layer 130 is the circular polarization plate, but in the present embodiment, the light blocking layer 130 is a light absorption layer. Since the present embodiment is substantially similar to the first embodiment except for this point, description of matters common to those of the first embodiment will be omitted.

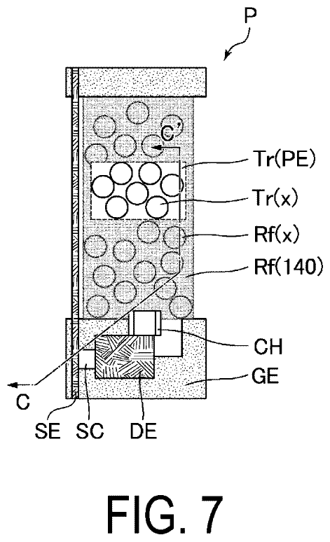

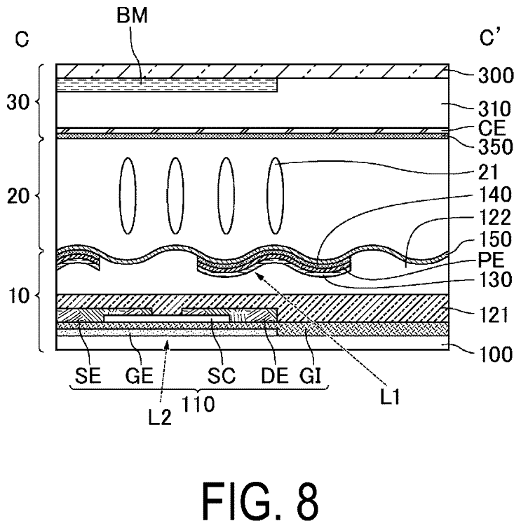

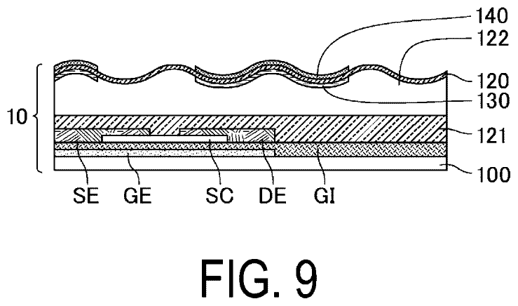

FIG. 7 is a schematic plan view of a pixel included in the display device 1 according to the present embodiment. FIG. 8 is a cross-sectional view taken along a line C-C′ in FIG. 7. FIG. 9 is a schematic cross-sectional view more specifically illustrating the first substrate 10 illustrated in FIG. 8 (the alignment film 150 is omitted). Also in the present embodiment, the pixel electrode PE electrically connected to the TFT 110 through the contact holes CH is disposed between the reflective layer 140 and the light blocking layer 130 (see FIG. 9). That is, in the reflective region Rf of each pixel P, it is preferable that the light blocking layer 130 and the pixel electrode PE be disposed on the back face side relative to the reflective layer 140 in an order of the pixel electrode PE and the light blocking layer 130 from the reflective layer 140 side (see FIG. 9). Note that the pixel electrode PE may be disposed on the back face side relative to the light blocking layer 130 (see a first modification, which will be described later).

One or more transparent layers (for example, a transparent electrode or an interlayer insulating film) may be disposed between the pixel electrode PE and the light blocking layer 130, but it is preferable that the light blocking layer 130 be disposed in contact with the pixel electrode PE. In particular, in the reflective region of each pixel, it is preferable that the observation face side of the pixel electrode PE be in contact with the reflective layer 140 and the back face side of the pixel electrode PE be in contact with the light blocking layer 130.

One layer or two or more layers of the interlayer insulating layers are preferably disposed between the TFT 110 and the light blocking layer 130. In FIG. 8 and FIG. 9, the first interlayer insulating layer 121 and the second interlayer insulating layer 122 are provided between the TFT 110 and the light blocking layer 130. The contact hole CH is formed at the interlayer insulating layers disposed between the pixel electrode PE and the TFT 110, and the pixel electrode PE is electrically connected to the TFT 110 through the contact hole CH. In the reflective region Rf of each pixel P, the first substrate 10 preferably includes the switching element 110, the interlayer insulating layers (the first interlayer insulating layer 121 and the second interlayer insulating layer 122 in FIG. 8 and FIG. 9), the light blocking layer 130, the pixel electrode PE, and the reflective layer 140 in this order from the back face side toward the observation face side (see FIG. 8 and FIG. 9).

In the present embodiment, the light blocking layer 130 is a light absorption layer. More specifically, the light blocking layer 130 is preferably made of a black material, and more preferably made of a black inorganic material and/or a black organic material. Although these materials are not particularly limited, examples of the black inorganic material include graphite and tantalum, and examples of the black organic material include an organic material that is usually used for a black matrix of a color filter.

The light blocking layer 130 may have a single layer structure or a layered structure of two or more layers. A thickness (total thickness in a case of the layered structure) of the light blocking layer 130 is not particularly limited, and is preferably 1 nm to 1 μm, for example. In particular, from the viewpoint of further suppressing reflection of light from the backlight unit, the thickness is more preferably 5 nm or more, further preferably 10 nm or more, particularly preferably 50 nm or more, and most preferably 100 nm or more. Additionally, the thickness of the light blocking layer 130 is more preferably 500 nm or less.

It is preferable that at least the surface of the light blocking layer 130 on the observation face side (that is, the surface on the reflective layer 140 side) have an uneven shape (uneven surface structure), and it is more preferable that both surfaces of the light blocking layer 130 on the observation face side and on the back face side have uneven shapes. For example, by using an organic insulating film having an uneven surface structure as at least one layer (for example, the second interlayer insulating layer 122 in FIG. 8 and FIG. 9) of the interlayer insulating layers disposed between the light blocking layer 130 and the TFT 110, the layers and the like (the light blocking layer 130, the pixel electrode PE, and the reflective layer 140 in the present embodiment) positioned on the observation face side relative to the interlayer insulating layer can have uneven shapes reflecting the uneven surface structure. In addition, it is preferable that the light blocking layer 130 have substantially the same planar pattern as the reflective layer 140 when viewed from the observation face side. The reflective layer 140 and the light blocking layer 130 are preferably individually patterned.

In the present embodiment, the light blocking layer 130 that is a light absorption layer is disposed on the back face side relative to the reflective layer 140. Due to this, the light L1 from the backlight unit is blocked by the light blocking layer 130 before entering the reflective layer 140, sufficiently suppressing reflection of the light L1 from the backlight unit (see FIG. 8). In other words, entrance of light into the TFT channel portion is sufficiently suppressed. Thus, since the negative shift of TFT characteristics is sufficiently suppressed, also in the display device 1 of the present embodiment, off characteristics of the TFT become excellent and a display defect (hazy unevenness) does not occur.

A preferred manufacturing method for the display device 1 of the present embodiment is the same as the manufacturing method described in the first embodiment except that a part of the preferred manufacturing method for the first substrate 10 is different as follows.

In the preferred manufacturing method for the first substrate 10 described above in the first embodiment, after forming the first interlayer insulating layer 121, an organic insulating film is applied to form the second interlayer insulating layer 122, and patterning is performed using a halftone mask or the like, thereby forming the uneven shape of the MRS on the surface of the second interlayer insulating layer 122 on the observation face side. After forming the light blocking layer 130 on the second interlayer insulating layer 122, a transparent electrode (for example, ITO) is formed as the pixel electrode PE, and further, the reflective layer 140 is formed. In this case, since the transparent electrode is interposed between the reflective layer 140 and the light blocking layer 130, patterning is individually performed for each of the reflective layer 140, the light blocking layer 130, and the transparent electrode. However, as described above, it is preferable that the reflective layer 140 and the light blocking layer 130 have substantially the same planar pattern. In this manner, the first substrate 10 is preferably prepared.

Note that the reflective layer 140 is not disposed in the transmissive region Tr in each pixel P. For example, the reflective region Rf including the reflective layer 140 and the transmissive region Tr not including the reflective layer 140 can be formed by forming the reflective layer 140 and the like on the support substrate 100 and then removing a part of the reflective layer 140 in manufacturing the first substrate 10. It is preferable that neither the reflective layer 140 nor the light blocking layer 130 be disposed in the transmissive region Tr.

### First Modification of Second Embodiment

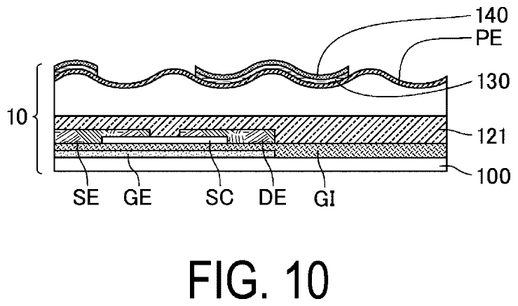

In the display device 1 according to the second embodiment, when the reflective layer 140 is made of, for example, silver or an alloy containing silver, a thin film of silver oxide may be formed as the light blocking layer 130 on the back face side relative to the reflective layer 140. That is, in the display device 1 of the present modification, the reflective layer 140 is made of silver or an alloy containing silver, and the light blocking layer 130 is made of silver oxide. In the reflective region Rf of each pixel P in the present modification, it is preferable that the light blocking layer 130 and the pixel electrode PE be disposed on the back face side relative to the reflective layer 140 in an order of the light blocking layer 130 and the pixel electrode PE from the reflective layer 140 side. Moreover, it is preferable that the observation face side of the light blocking layer 130 be in contact with the reflective layer 140 and the back face side of the light blocking layer 130 be in contact with the pixel electrode PE (see FIG. 10). FIG. 10 is a schematic cross-sectional view specifically illustrating the first substrate 10 included in the display device 1 according to the present modification. In FIG. 10, the alignment film 150 is omitted.

A preferred manufacturing method for the display device 1 of the present modification is the same as the manufacturing method described in the second embodiment except that a part of the preferred manufacturing method for the first substrate 10 is different as follows.

In the preferred manufacturing method for the first substrate 10 described above in the second embodiment, after forming the transparent electrode (for example, ITO) as the pixel electrode PE on the second interlayer insulating layer 122, silver sputtering with oxygen introduced is performed to form a silver oxide thin film (that is, the light blocking layer 130). After that, sputtering with oxygen blocked is performed to form the reflective layer 140. In such a manufacturing method, the light blocking layer 130 and the reflective layer 140 can be formed at the same time. Thereafter, the light blocking layer 130 and the reflective layer 140 are patterned using, for example, a mixed solution of ammonia water and hydrogen peroxide water, enabling only silver and silver oxide to be selectively and collectively etched, and thus simplifying the process.

Although the embodiments of the disclosure have been described above, all the individual matters described above can be applied to the entirety of the disclosure.

The display device 1 according to the disclosure will be described in more detail with reference to Examples and the like below, but the display device 1 according to the disclosure is not limited to only aspects of Examples.

### Comparative Example 1

A liquid crystal display device 1R having the structure illustrated in FIG. 1 was prepared. In the liquid crystal display device 1R, the first substrate 10 has the structure illustrated in FIG. 11, the display layer 20 is a liquid crystal layer, and the second substrate 30 has a structure similar to that of the second substrate 30 in FIG. 2. The liquid crystal display device 1R includes the light source 40 on the back face side, and the reflective layer 140 having an uneven shape of an MRS. The reflective layer 140 is provided on a side of the first substrate 10 positioned on the back face side, of a pair of substrates sandwiching the liquid crystal layer 20 (see FIG. 11). ITO films were used as the pixel electrode PE and the common electrode CE, an organic insulating film (with a film thickness of 2000 nm) was used as the second interlayer insulating layer 122, and an aluminum film (with a film thickness of 100 nm) was used as the reflective layer 140. As the backlight unit 40, a backlight unit including an LED light source and two brightness enhancement films (BEFs) was used. The illuminance of light from the backlight unit was 10000 cd/m². FIG. 11 is a schematic cross-sectional view specifically illustrating the first substrate 10 included in the liquid crystal display device 1R of the present example.

While the TFT 110 of the liquid crystal display device 1R was being irradiated with light from the backlight unit, a gate voltage Vg=−10 V was applied and energization was performed at 60° C. for one hour. This is called a Light Negative Bias Temp. (LNBT) Stress test. For each example, ΔVth before and after the LNBT test and an aging time when a display defect (hazy unevenness) occurred are shown in Table 1.

In the measurement of Vth of the TFT 110, a drain current Id was checked while a voltage of 10 V was being applied between the source and the drain and a gate voltage Vg was being swept by using a semiconductor parameter analyzer (for example, “B1500A” manufactured by Keysight Technologies, or the like), and from the Vg-Id characteristics waveform, Vth was determined as Vg at which the drain current Id reached 10-9 A, which was a current value at which hazy unevenness started to occur. After determining Vth of each TFT at both time points before the LNBT test and after the LNBT test for one hour, ΔVth was calculated by the following equation.

ΔVth=(Vth after the LNBT test)−(Vth before the LNBT test)

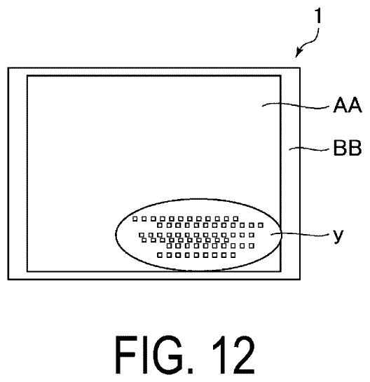

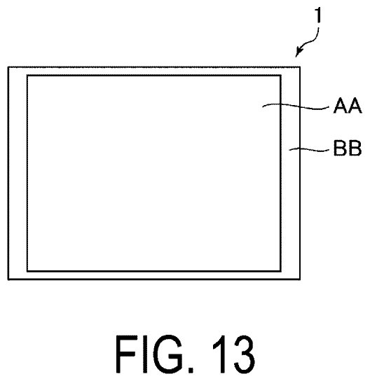

In addition, the liquid crystal display device 1R was driven at a low frequency (1 Hz), and an aging test was performed for 1000 hours in a state of transmissive display (that is, in a state where the backlight unit 40 was turned on). Thereafter, when the state of the display region AA of the liquid crystal display device 1R was visually observed, clustered bright spots (hazy unevenness) y were observed in the display region AA (see FIG. 12). FIG. 12 is a plan view conceptually illustrating a state of the display region AA after performing the aging test for 1000 hours in this example. Note that FIG. 13 is a plan view conceptually illustrating a state of the display region AA before the aging test. A frame region BB is a region outside the display region AA.

### Comparative Example 2

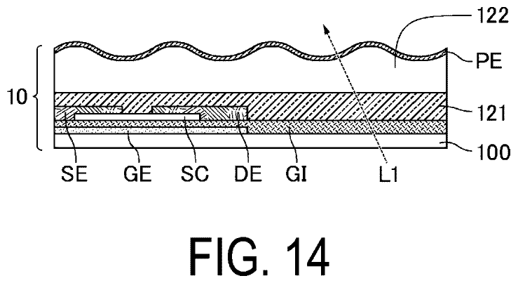

The liquid crystal display device 2R having a structure obtained by removing the reflective layer 140 from the liquid crystal display device 1R of Comparative Example 1 was prepared (see FIG. 14). FIG. 14 is a schematic cross-sectional view specifically illustrating the first substrate 10 included in the liquid crystal display device 2R of this example. The liquid crystal display device 2R does not include the reflective layer 140 and thus corresponds to a transmissive display device. For this liquid crystal display device 2R, ΔVth before and after the LNBT test and an aging time when a display defect occurred were determined as in Comparative Example 1. The results are shown in Table 1.

### Comparative Example 3

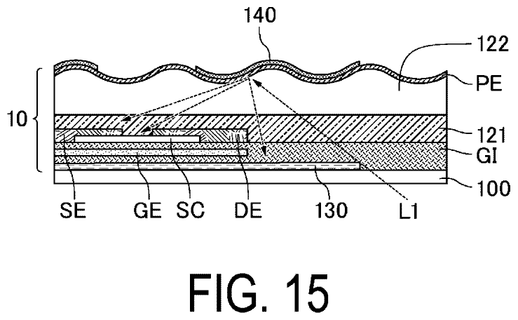

A liquid crystal display device 3R having the same structure as the liquid crystal display device 1R of Comparative Example 1 except that the light blocking layer 130 is disposed on the back face side relative to the TFT channel portion SC was prepared (see FIG. 15). FIG. 15 is a schematic cross-sectional view specifically illustrating the first substrate 10 included in the liquid crystal display device 3R of this example. For this liquid crystal display device 3R, ΔVth before and after the LNBT test and an aging time when a display defect occurred were determined as in Comparative Example 1. The results are shown in Table 1.

### Example 1

A liquid crystal display device 1A corresponding to the display device 1 of the first embodiment was prepared (see FIG. 1 to FIG. 6). The liquid crystal display device 1A has substantially the same pixel structure as that of the liquid crystal display device 1R prepared in Comparative Example 1 except that the light blocking layer 130 is disposed on the observation face side relative to the source bus line SE and the drain wiring line DE of the TFT 110. In this example, a circular polarization plate constituted by the polarizer 131 and the λ/4 plate 132 was used as the light blocking layer 130. For the liquid crystal display device 1A, ΔVth before and after the LNBT test and an aging time when a display defect occurred were determined as in Comparative Example 1. The results are shown in Table 1.

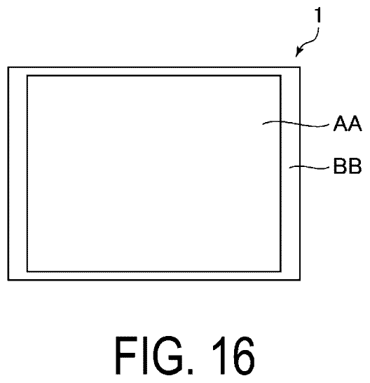

In addition, the liquid crystal display device 1A was driven at a low frequency (1 Hz), and an aging test was performed for 1000 hours in a state of transmissive display (that is, in a state where the backlight unit 40 was turned on). Thereafter, when a state of the display region AA of the liquid crystal display device 1A was observed, clustered bright spots (hazy unevenness) y were not observed in the display region AA (see FIG. 16). FIG. 16 is a plan view conceptually illustrating a state of the display region AA after performing the aging test for 1000 hours in Example 1. FIG. 13 is a plan view conceptually illustrating a state of the display region AA before the aging test.

### Example 2

A liquid crystal display device 2A corresponding to the display device 1 according to the first modification of the second embodiment was prepared (see FIG. 1 and FIG. 7 to FIG. 10). The liquid crystal display device 2A has substantially the same pixel structure as that of the liquid crystal display device 1R prepared in Comparative Example 1 except that the light blocking layer 130 is disposed on the observation face side relative to the source bus line SE and the drain wiring line DE of the TFT 110. In this example, a thin film of silver oxide was formed as the light blocking layer 130 on the back face side relative to the reflective layer 140. For the liquid crystal display device 2A, ΔVth before and after the LNBT test and an aging time when a display defect occurred were determined as in Comparative Example 1. The results are shown in Table 1.

In addition, the liquid crystal display device 2A was driven at a low frequency (1 Hz), and an aging test was performed for 1000 hours in a state of transmissive display (that is, in a state where the backlight unit 40 was turned on). Thereafter, when the state of the display region AA of the liquid crystal display device 2A was observed, clustered bright spots (hazy unevenness) y were not observed in the display region AA (see FIG. 16). FIG. 16 is also a plan view conceptually illustrating a state of the display region AA after performing the aging test for 1000 hours in Example 2. FIG. 13 is a plan view conceptually illustrating a state of the display region AA before the aging test.

TABLE 1

| | Comparative | Comparative | Comparative | | |
|---|---|---|---|---|---|
| | Example 1 | Example 2 | Example 3 | Example 1 | Example 2 |
| ΔVth | −4.0 V | −1.2 V | −2.5 V | −1.5 V | −1.2 V |
| Time when hazy | Within | Longer | Within | Longer | Longer |
| unevenness occurred | 250 h | than 1000 h | 500 h | than 1000 h | than 1000 h |

As can be seen from Table 1, in Comparative Example 2, the shift of ΔVth was small, and the display defect (hazy unevenness) had not occurred until at least 1000 hours. That is, it can be seen that no hazy unevenness occurs in the transmissive display device. On the other hand, in Comparative Example 1, ΔVth was largely shifted. Due to the influence of the large shift, the display defect occurred within 250 hours. In Comparative Example 3, although the shift of ΔVth was smaller than that in Comparative Example 1, the shift was still large and the display defect occurred within 500 hours. On the other hand, in Example 1, the shift of ΔVth was small, and the display defect had not occurred until at least 1000 hours. In Example 2, the shift of ΔVth was further smaller than that in Example 1, and the display defect had not occurred until at least 1000 hours.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A display device comprising:
a light source, a first substrate including a switching element including an oxide semiconductor layer, a display layer, and a second substrate, in this order from a back face side to an observation face side; and
a plurality of pixels arranged in a matrix in a display region,
wherein the first substrate includes a light blocking layer and a reflective layer on the observation face side relative to the switching element,
the light blocking layer is positioned between the switching element and the reflective layer,
at least a surface of the reflective layer on the back face side has an uneven shape, and
each of the plurality of pixels includes a reflective region and a transmissive region, the reflective region is configured to reflect light at the reflective layer and to perform display, and the transmissive region is configured to transmit light and to perform display.

2. The display device according to claim 1,
wherein the first substrate includes an interlayer insulating film between a source bus line and a drain wiring line each of which is electrically connected to the switching element and the light blocking layer.

3. The display device according to claim 1,
wherein the light blocking layer is a circular polarization plate.

4. The display device according to claim 3,
wherein each of the plurality of pixels includes a pixel electrode electrically connected to the switching element, and
in the reflective region of each of the plurality of pixels, the light blocking layer and the pixel electrode are disposed on the back face side relative to the reflective layer in an order of the pixel electrode and the light blocking layer.

5. The display device according to claim 4,
wherein the first substrate includes an interlayer insulating film between the pixel electrode and the light blocking layer.

6. The display device according to claim 1,
wherein the light blocking layer is a light absorption layer.

7. The display device according to claim 6,
wherein the light blocking layer is made of a black inorganic material and/or a black organic material.

8. The display device according to claim 6,
wherein each of the plurality of pixels includes a pixel electrode electrically connected to the switching element, and
in the reflective region of each of the plurality of pixels, the light blocking layer and the pixel electrode are disposed on the back face side relative to the reflective layer in an order of the pixel electrode and the light blocking layer.

9. The display device according to claim 8,
wherein in the reflective region of each of the plurality of pixels, the observation face side of the pixel electrode is in contact with the reflective layer, and the back face side of the pixel electrode is in contact with the light blocking layer.

10. The display device according to claim 6,
wherein each of the plurality of pixels includes a pixel electrode electrically connected to the switching element, and
in the reflective region of each of the plurality of pixels, the light blocking layer and the pixel electrode are disposed on the back face side relative to the reflective layer in an order of the light blocking layer and the pixel electrode.

11. The display device according to claim 10,
wherein in the reflective region of each of the plurality of pixels, the observation face side of the light blocking layer is in contact with the reflective layer, and the back face side of the light blocking layer is in contact with the pixel electrode.

12. The display device according to claim 6,
wherein at least a surface of the light blocking layer on the back face side has an uneven shape.

13. The display device according to claim 4,
wherein at least a surface of the pixel electrode on the back face side has an uneven shape.

14. The display device according to claim 1,
wherein a polarization plate is provided on the observation face side relative to the second substrate.

15. The display device according to claim 1,
wherein the display layer is a liquid crystal layer.

16. The display device according to claim 1, further comprising:
a drive circuit configured to drive the display device,
wherein the drive circuit is configured to switch between a first drive mode and a second drive mode, and in the first drive mode, the display device is configured to be driven at a first frequency, and in the second drive mode, the display device is configured to be driven at a second frequency lower than the first frequency.

17. The display device according to claim 16,
wherein the light source is turned on in the second drive mode.

18. The display device according to claim 1,
wherein the oxide semiconductor layer includes InGaZnOx including indium (In), gallium (Ga), zinc (Zn), and oxygen (O) as main components.
